(19) United States
(12) Patent Application Publication
(10) Pub. No.: US 2005/0140247 A1
(43) Pub. Date: Jun. 30, 2005

(54) Film bulk acoustic wave resonator device and manufacturing method thereof

(76) Inventor: Joo Ho Lee, Suwon (KR)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/855,414

(22) Filed: May 28, 2004

(30) Foreign Application Priority Data
Dec. 26, 2003 (KR) 2003-97330

(51) Int. Cl. H01L 41/08

(52) U.S. Cl. 310/320

(57) ABSTRACT

Disclosed herein is an FBAR (film bulk acoustic wave resonator) device and a manufacturing method thereof. The FBAR device comprises a substrate, a resonance unit including a lower electrode, a piezoelectric film, and an upper electrode, which are successively stacked on the substrate, and a passivation layer formed substantially throughout an upper surface and peripheral surface of the resonance unit in order to protect the resonance unit. A partial region of the passivation layer formed on at least the upper electrode has a thickness required to compensate for a difference between a resonant frequency of the resonance unit and a desired target resonant frequency.

### BACKGROUND OF THE INVENTION

1. Field of the Invention

The present invention relates to a film bulk acoustic wave resonator (hereinafter, referred to as an FBAR), and more particularly to an FBAR device and a manufacturing method thereof, which can achieve ease of frequency adjustment, and minimize a risk in generation of poor products during a packaging process.

2. Description of the Related Art

According to the recent trend wherein mobile communication terminals have tended to become much leaner and enhanced and diversified in their quality and functions, techniques related with constituent components of the mobile communication terminals, for example radio frequency (RF) components, are rapidly being developed. Among the RF components, especially, an FBAR (film bulk acoustic wave resonator) is in the spotlight as an essential passive filter component of the mobile communication terminals by virtue of its advantages in that it has a lower insertion loss than other filters, and it can achieve a desired level of integration and miniaturization.

In general, an FBAR device is a thin film type device wherein a piezoelectric thin film layer made of ZnO or AlN is formed on a semiconductor substrate made of silicon or GaAs, resulting in a resonant frequency from the combination of a mechanical stress and a load produced at a surface of the piezoelectric thin film layer. The resonant frequency of such an FBAR device is determined by the total thickness of its resonance unit comprising upper and lower electrodes as well as the piezoelectric thin film layer. With the present technical level, however, it is substantially impossible to make respective FBAR devices in a wafer to have the same thickness as each other within a tolerance range of approximately 1 percent of the thickness. Moreover, the upper electrode made of metal tends to cause an oxidation phenomenon thereof, resulting in disadvantageous variation in the resonant frequency of the FBAR device. Such a frequency variation problem of the FBAR device, especially, may be increased during a packaging process due to oxidation.

The FBAR device, therefore, sincerely requires a solution for adjusting a resonant frequency thereof to have a constant value, and stabilizing the adjusted resonant frequency.

Considering one example of conventional solutions for adjusting the resonant frequency of the FBAR device, it adjusts the overall thickness of the FBAR device through etching or vapor deposition implemented on an upper metal layer, namely, an upper metal electrode of the FBAR device. This solution, however, still exhibits an oxidation problem of the upper metal electrode during a subsequent process.

In order to solve this oxidation problem, U.S. patent publication No. 2003-0098631 (achieved by an applicant named in AGILENT TECHNOLOGIES, INC) discloses an FBAR device wherein a thermal oxide film having a predetermined thickness is additionally formed by performing an intentional thermal oxidation process of its upper electrode made of molybdenum (Mo) in an atmosphere of oxygen. The obtained structure of such a FBAR device with the thermal oxide film is schematically shown in FIGS. 1a and 1b.

Referring to FIGS. 1a and 1b, the FBAR device of the type as discussed above, designated as reference number 10, comprises a silicon substrate 11 formed at an upper surface thereof with a resonance unit. The resonance unit comprises a lower electrode 14, a piezoelectric layer 15, and an upper electrode 16, which are successively stacked on an air gap (A) defined in the silicon substrate 11. Said U.S. patent publication No. 2003-0098631 proposes a frequency adjustment solution using a thermal oxide film 18, which is formed at an upper surface of the upper electrode 16 at a relatively low temperature (for example, approximately 200 to 300° C.) by means of a hot plate process or RTA (rapid thermal annealing) equipment. As a result of forming the thermal oxide film 18 having an appropriate thickness, the FBAR device 10 enables a resonant frequency thereof to be accurately adjusted from a present value to a desired target value. The thermal oxide film 18 further functions to restrict excessive oxidation of the upper electrode 16, resulting in stabilization in the adjusted frequency.

The above described conventional FBAR device 10, however, has a problem in that there is a limitation of the thickness of the thermal oxide film 18 obtainable through the thermal oxidation process, resulting in a considerable restriction in adjustable frequency range. In view of frequency stabilization, further, the presence of the thermal oxide film 18 only affects to delay an oxidation speed of the upper electrode made of metal during a subsequent process, and thus it is difficult to completely prevent an actual oxidation progress itself.

Furthermore, since the thermal oxide film 18 formed on the upper electrode 16 tends to be damaged in a subsequent process, especially, in the manufacture of a package accompanying with a photoresist process or slicing process, there may be a risk of an unintentional sudden frequency variation.

As can be seen from the above description related to the prior art, there has been required a new solution in the art for adjusting a resonant frequency up to a desired sufficient level as well as stably maintaining the adjusted resonant frequency even during a subsequent packaging process.

### SUMMARY OF THE INVENTION

Therefore, the present invention has been made in view of the above problems, and it is an object of the present invention to provide an FBAR device, which can achieve appropriate adjustment in a resonant frequency thereof and stable protection of its resonance unit during a subsequent process. This objective is accomplished by virtue of a passivation layer formed substantially throughout the resonance unit, rather than being formed only on an upper electrode of the resonance unit.

It is another object of the present invention to provide an FBAR device, and a method of manufacturing an FBAR device package, which shows additional advantages in relation to the formation of a cap structure in a chip scale packaging or wafer level packaging process.

In accordance with one aspect of the present invention, the above and other objects can be accomplished by the provision of a film bulk acoustic wave resonator (FBAR) device comprising: a substrate; a resonance unit including a lower electrode, a piezoelectric film, and an upper electrode, which are successively stacked on the substrate; and a passivation layer formed substantially throughout an upper surface and a peripheral surface of the resonance unit in order to protect the resonance unit, wherein a partial region of the passivation layer located on at least the upper electrode has a thickness required to compensate for a difference between a resonant frequency of the resonance unit and a desired target resonant frequency.

Preferably, the passivation layer may be made of an oxide or nitride composed of elements selected from among the group consisting of Si, Zr, Ta, Ti, Hf, and Al, and more preferably, the passivation layer may be made of a material selected from among the group consisting of SiO₂, Si₃N₄, HfO, Al₂O₃, AlN and AlNOₓ. The passivation layer may be formed by sputtering, evaporation, or chemical vapor deposition (CVD).

Preferably, the FBAR device in accordance with an embodiment of the present invention may further comprise connection pads formed on the substrate so that they are connected to the upper and lower electrodes, respectively, and the connection pads may be made of Au.

In general, the FBAR device is basically classified into an air gap manner device and a bragg reflection manner device according to an insulation structure between the substrate and a resonance unit, and the present invention can be effectively applied into both the devices. Therefore, the substrate may include an air gap formed at a region where the resonance unit is formed thereabove. Alternatively, the substrate may have a reflective film structure obtained through bragg reflection.

In accordance with another aspect of the present invention, the above and other objects can be accomplished by the provision of a method of manufacturing an FBAR device comprising the steps of: a) preparing a substrate; b) forming a resonance unit by successively stacking a lower electrode, a piezoelectric film, and an upper electrode on the substrate; c) calculating a thickness of the resonance unit required to compensate for a difference between a resonant frequency of the resonance unit and a desired target resonant frequency; and d) forming a passivation layer substantially throughout an upper surface and a peripheral surface of the resonance unit for protecting the resonance unit so that a partial region of the passivation layer located on at least the upper electrode has the calculated thickness.

Preferably, before the step d), the method of the present invention further comprises the step of: e) forming connection pads on the substrate so that they are connected to the upper and lower electrodes, respectively.

Preferably, the step d) may include the steps of: d-1) forming the passivation layer on the substrate above the resonance unit so that the partial region of the passivation layer located on at least the upper electrode has the calculated thickness; and d-2) selectively removing the passivation layer so that partial regions of the connection pads to be bonded to an exterior circuit are exposed to the outside.

Preferably, the step a) may include the steps of: a-1) forming a sacrificial material region at the substrate, the sacrificial material region being for use in the formation of an air gap; and a-2) forming an insulation layer on the sacrificial material region, and the method of the present invention may further comprise the steps of: f) selectively removing the insulation layer, so as to form a via hole communicating with the sacrificial material region; and g) removing the sacrificial material region through the via hole, so as to form the air gap.

Preferably, the step d-2) and the step f) may be simultaneously performed through a single process using a photoresist film, the sacrificial material region may be made of a polysilicon material, the step g) may be an etching step of the sacrificial material region using XeF₂. Advantageously, in the step g), the passivation layer may protect the upper electrode.

In accordance with yet another aspect of the present invention, the above and other objects can be accomplished by the provision of a method of manufacturing an FBAR device package comprising the steps of: a) preparing a substrate; b) forming a resonance unit by successively stacking a lower electrode, a piezoelectric film, and an upper electrode on the substrate; c) calculating a thickness of the resonance unit required to compensate for a difference between a resonant frequency of the resonance unit and a desired target resonant frequency; d) forming a passivation layer substantially throughout an upper surface and peripheral surface of the resonance unit for protecting the resonance unit so that a partial region of the passivation layer located on at least the upper electrode has the calculated thickness; and e) forming a cap structure so as to seal the resonance unit formed with the passivation layer.

In the above package manufacturing method in accordance with the present invention, various kinds of cap structures can be employed. When the cap structure is formed by making use of dry films, the step e) may include the steps of: e-1) forming a side wall structure surrounding the resonance unit by applying a first dry film; and e-2) forming a roof structure on the side wall structure by applying a second dry film thereon. Preferably, after the step e-1) and before the step e-2), the method of the present invention may further comprise the step of: f) removing the sacrificial material region for the formation of the air gap.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a and 1b are a side sectional view and a plan view, respectively, illustrating a conventional FBAR device;

FIGS. 2a and 2b are a side sectional view and a plan view, respectively, illustrating an FBAR device in accordance with an embodiment of the present invention;

FIGS. 3a to 3h are side sectional views, respectively, illustrating the sequential steps of manufacturing an FBAR device in accordance with the present invention; and

FIGS. 4a to 4e are sectional views, respectively, illustrating the sequential steps of manufacturing an FBAR device package in accordance with the present invention.

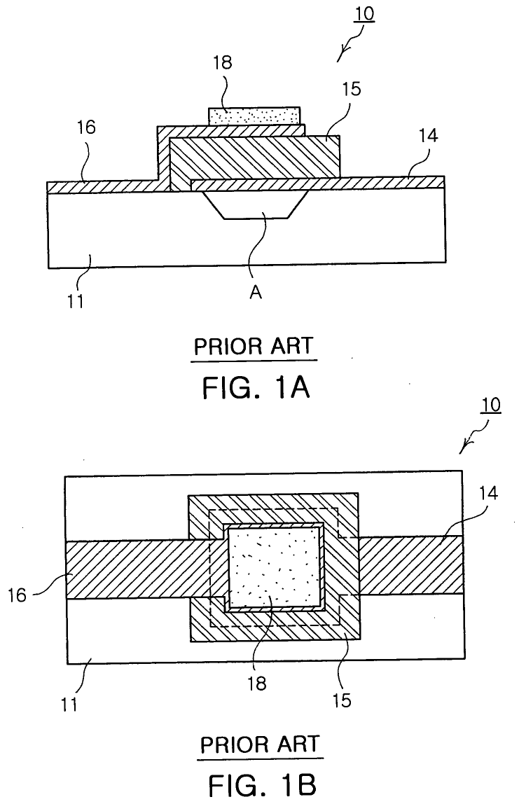

### DESCRIPTION OF THE PREFERRED EMBODIMENTS

Now, the present invention will be described, with reference to the accompanying drawings.

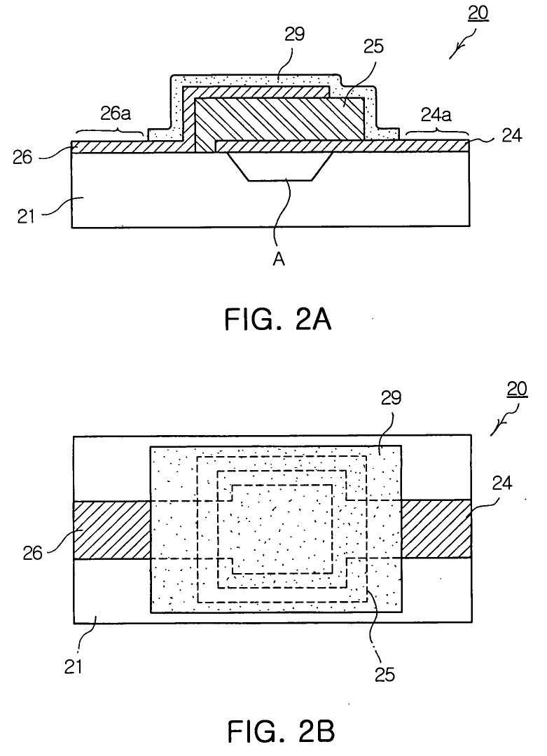

FIGS. 2a and 2b are a side sectional view and a plan view, respectively, illustrating an FBAR device in accordance with an embodiment of the present invention.

Referring to FIG. 2b along with FIG. 2a, the FBAR device of the present invention, designated as reference numeral 20, comprises a substrate 21 formed at an upper surface thereof with a resonance unit. The resonance unit comprises a lower electrode 24, a piezoelectric layer 25, and an upper electrode 26, which are successively stacked on the substrate 21 so that they are positioned above an air gap (A) defined in the substrate 21. Mainly, the substrate 21 may be a silicon substrate, the upper and lower electrodes 26 and 24 may be made of molybdenum (Mo), and the piezoelectric layer 25 may be made of aluminum nitride (AlN), but are not limited thereto.

The FBAR device 20 in accordance with the present invention further comprises a passivation layer 29. Preferably, as shown in FIGS. 2a and 2b, the passivation layer 29 is formed substantially throughout an upper surface and peripheral surface of the resonance unit, while remaining certain partial regions of the upper and lower electrodes 26 and 24 where connectors 26a and 24a will be formed.

The passivation layer 29 enables easy and effective adjustment in a resonant frequency of the FBAR device 20. That is, as shown in FIG. 2a, the passivation layer 29 is formed at the upper surface of the resonance unit, namely, at an upper surface of the upper electrode 26 in such a manner that it increases a thickness of a certain region corresponding to an actual resonance region. Such a thickness increase in the actual resonance region enables easy adjustment in the resonant frequency. In the present invention, therefore, the resonant frequency of the FBAR device can be realized in such a manner that, after completion of the resonance unit, a resonant frequency produced by the resonance unit is measured, and then the passivation layer is formed into a thickness suitable for compensating for a difference between the measured resonant frequency and a desired target frequency.

The passivation layer 29 further enables stable maintenance a resulting adjusted resonant frequency in view of frequency stabilization. This is accomplished since the passivation layer 29 has substantially no risk of its thickness change or damage due to oxidation during a subsequent process. The passivation layer 29 furthermore functions to safely protect the resonance unit during the manufacture of an FBAR device package accompanying a photoresist process or slicing process.

The passivation layer 29 may be made of an oxide or nitride composed of elements selected from among the group consisting of Si, Zr, Ta, Ti, Hf, and Al. More preferably, the passivation layer 29 may be made of a material selected from among the group consisting of SiO₂, Si₃N₄, HfO, Al₂O₃, AlN and AlNOₓ. Differently from a conventional thermal oxide film, the passivation layer 29 can be sufficiently grown up to a desired thickness, and has an easy formation process.

Several other advantages and effects of the present invention will be understood by reading a follow description related to an FBAR device manufacturing method and an FBAR device package manufacturing method in accordance with the present invention. According to the present invention, especially, a formation process of the passivation layer 29 provides several advantages as it is usefully combined with an air gap formation process using a sacrificial material region and a package manufacturing method.

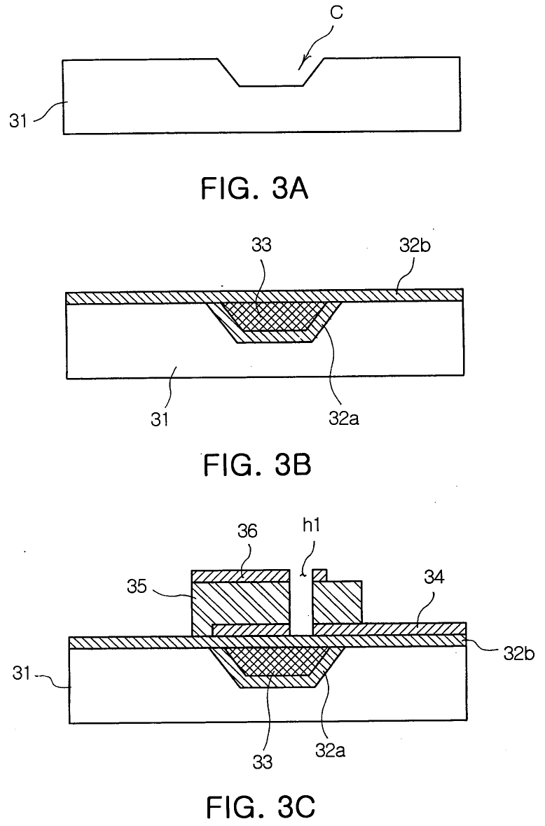

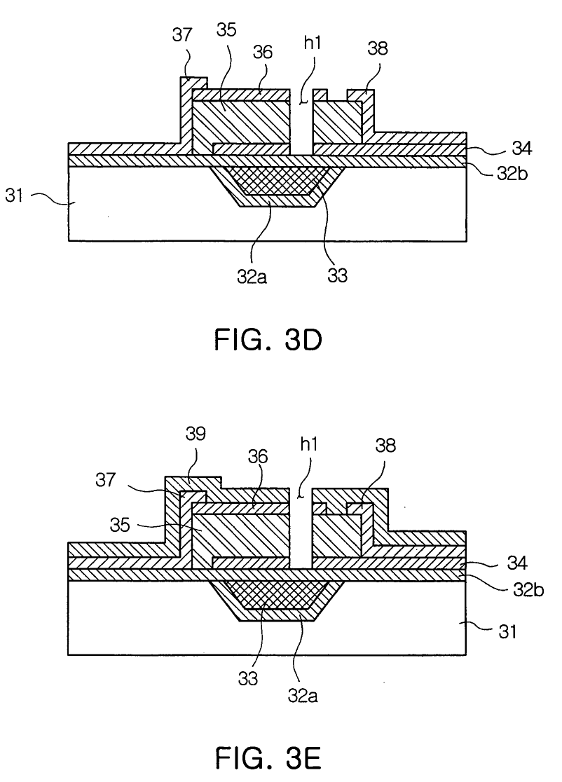

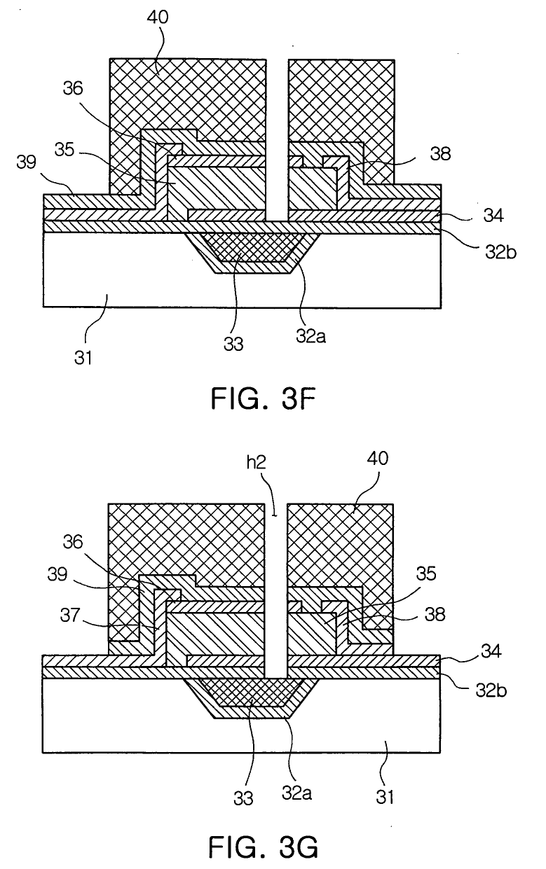

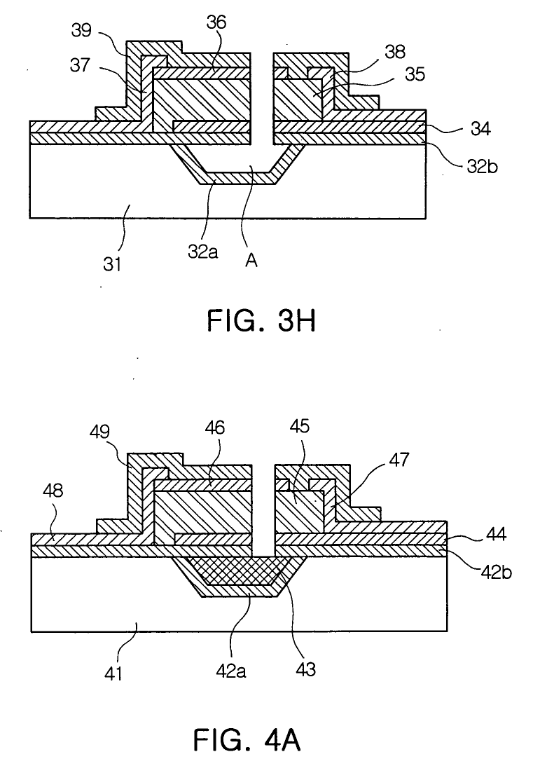

FIGS. 3a to 3h are side sectional views, respectively, illustrating the sequential steps of manufacturing an FBAR device in accordance with the present invention.

As shown in FIG. 3a, first, a silicon substrate 31 of the FBAR device is prepared so that a cavity (C) is formed at an upper surface thereof. The cavity (C) is for the formation of an air gap serving as isolation means between the substrate 31 and a resonance unit to be formed in a subsequent process.

Then, as shown in FIG. 3b, the cavity (C) of the silicon substrate 31 is filled with a sacrificial material, thereby forming a sacrificial material region 33. The sacrificial material may be a polysilicon material. Meanwhile, before the formation of the sacrificial material region 33, a first insulation layer 32a is formed throughout an inner surface of the cavity (C) defined in the silicon substrate 31, in order to protect the silicon substrate 31 from an etching process for the formation of an air gap. Similarly, after the formation of the sacrificial material region 33, the silicon substrate 31 is formed at the upper surface thereof with a second insulation layer 32b. The second insulation layer 32b serves to prevent the etching of a lower electrode, which is designated as reference numeral 34 in FIG. 3c.

Referring to FIG. 3c, on a portion of the insulation layer 32b located above the sacrificial material region 33 are successively stacked the lower electrode 34, a piezoelectric film 35, and an upper electrode 36, resulting in a resonance unit. The upper and lower electrodes 36 and 34 and piezoelectric film 35 can be formed by repeating respective film growth processes and etching processes. As a result of the appropriate etching processes, a via hole h1 is formed to vertically penetrate through the piezoelectric film 35 as shown in FIG. 3c. Such a via hole h1 is for use in an etching process of the sacrificial material region 33.

After completing the formation of the resonance unit, as shown in FIG. 3d, connection pads 37 and 38 are formed on the silicon substrate 31 so that they are connected to the upper and lower electrodes 36 and 34. The connection pads 37 and 38 may be made of Au. In a subsequent process, the connection pads 37 and 38 serve as connectors to be connected with an exterior circuit. The connection pad 37 made of Au, especially, serves to connect the upper electrode 36 to a certain region of the silicon substrate 31 to be connected to an exterior circuit.

In succession, as shown in FIG. 3e, a passivation layer 39 is formed to cover all of the above enumerated components including the upper and lower electrodes 36 and 34, piezoelectric film 35, and connection pads 37 and 38. The passivation layer 39 may be made of oxide or nitride composed of elements selected from among the group consisting of Si, Zr, Ta, Ti, Hf, and Al. More preferably, the passivation layer 39 may be made of a material selected from among the group consisting of SiO₂, Si₃N₄, HfO, Al₂O₃, AlN and AlOₓ. The passivation layer 39 may be formed through a conventional film growth process such as sputtering, evaporation, or chemical vapor deposition (CVD). In this case, a portion of the passivation layer 39 provided on the upper electrode 36 is a portion for use in the adjustment of a resonant frequency, and has a thickness suitable for adjusting the previously measured resonant frequency of the resonance unit to a desired target frequency.

Next, as shown in FIG. 3f, a photoresist film 40 is applied onto the passivation layer 39, and is patterned so that partial regions of the passivation layer 39 located on the connectors to be bonded to an exterior circuit and a portion of the second insulation layer 32b communicating with the via hole h1 are exposed to the outside.

Then, as shown in FIG. 3g, an etching process of the passivation layer 39 using the patterned photoresist film 40 is performed. Through this etching process, partial regions of the connection pads 37 and 38 to be bonded to the exterior circuit are exposed to the outside, and the portion of the second insulation layer 32b is selectively removed, thereby producing a via hole h2 communicating with the sacrificial material region 33.

Finally, as shown in FIG. 3h, the photoresist film 40 is removed and then the sacrificial material region 33 is removed, resulting in an air gap (A). The sacrificial material region 33 may be made of a polysilicon material, and in this case, the sacrificial material region 33 can be removed by using XeF₂. The use of XeF₂ does not affect the connection pads 37 and 38 made of Au, but may affect the upper and lower electrodes 36 and 34 made of Mo as an etchant. In order to eliminate such an unintentional influences, according to the present invention, the passivation layer 39 can act as a protecting layer for the upper electrode 36, and the like.

Although FIGS. 3a to 3h illustrate an embodiment wherein an air gap (A) is formed through the formation of the cavity C, those skilled in the art will appreciate that the present invention can be similarly applied to another embodiment wherein an air gap is formed by constructing a separate membrane structure on a substrate. Furthermore, the present invention is applicable to a certain manner wherein a substrate is structured by using a bragg reflection method for allowing the substrate to function as isolation means between the substrate and a resonance unit to be formed thereon.

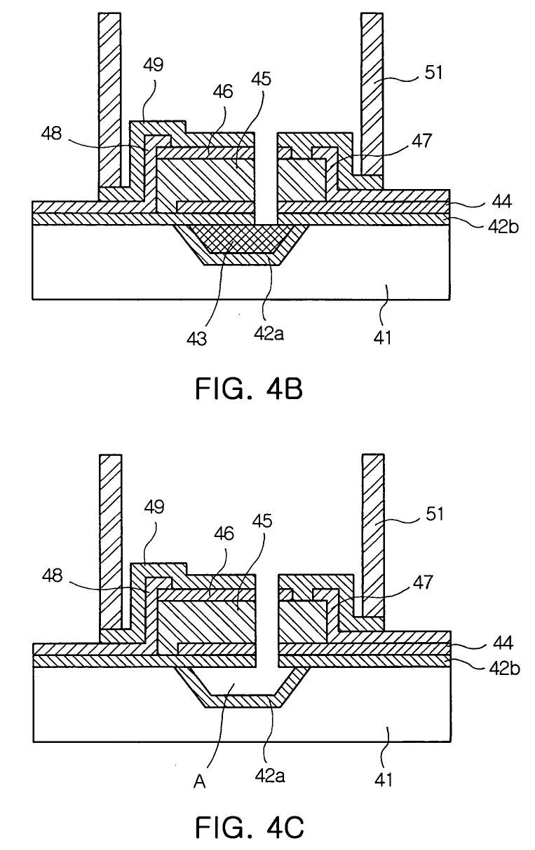

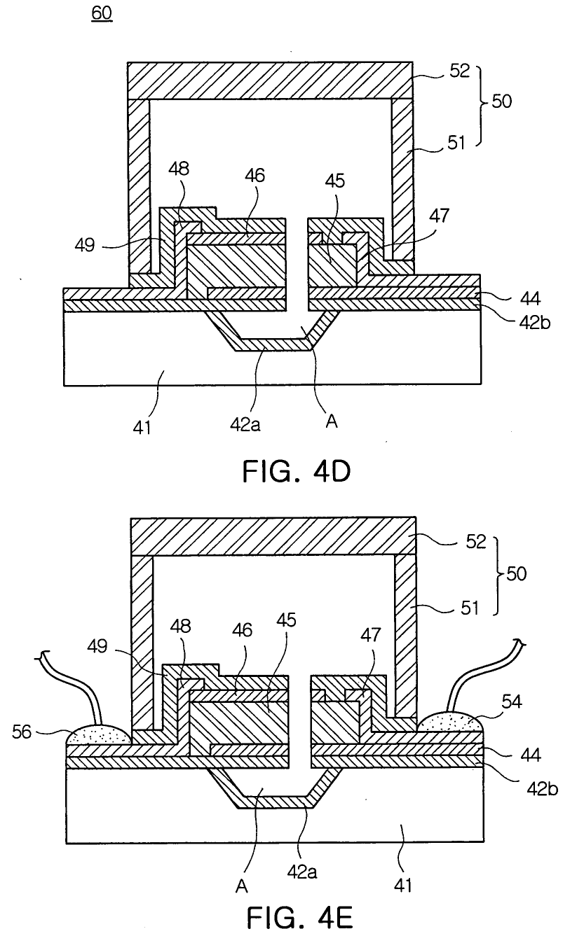

FIGS. 4a to 4e are sectional views illustrating the sequential steps of manufacturing an FBAR device package in accordance with the present invention. The FBAR device package manufacturing method of the present invention basically comprises the above described FBAR device manufacturing method. That is, FIGS. 4a to 4e are sectional views illustrating a method of manufacturing a cap structure for use in the formation of a package in a state wherein the FBAR device is previously manufactured. The cap structure employed in the present embodiment is a cap structure using a dry film, but the present invention is not limited thereto.

Referring to FIG. 4a, first, it shows the same state as FIG. 3g, except that the photoresist film 40 is removed from the FBAR device. That is, a silicon substrate 41 of the FBAR device is formed with a cavity, and inside the cavity are formed a first insulation layer 42a for the protection of the substrate 41, and a sacrificial material region 43. Then, after a second insulation layer 42b for the protection of a lower electrode 44 is formed at an upper surface of the silicon substrate 41, the lower electrode 44, a piezoelectric film 45, and an upper electrode 46 are successively stacked on the silicon substrate 41 above the sacrificial material region 43, thereby forming a resonance unit. In succession, a pair of connection pads 48 and 47 are formed so that they are connected to the upper and lower electrodes 46 and 44, respectively, and a passivation layer 49 is formed so that it covers all of the constituent components as stated above. After that, through a photoresist process as shown in FIGS. 3f and 3g, certain partial regions of the passivation layer 49 is selectively etched so that partial portions of the connection pads 47 and 48 to be bonded to an exterior circuit and a portion of the sacrificial material region 43 are exposed to the outside. Finally, as the photoresist film 40 is removed, the FBAR device shown in FIG. 4a can be completed.

In a state wherein the FBAR device is prepared as stated above, referring to FIG. 4b, a side wall structure 51 is formed by using a dry film so that it surrounds the resonance unit. This process is performed in such a manner that, after the dry film is applied throughout an upper surface of the FBAR device, it is selectively removed. In the present embodiment, during the formation of the side wall structure 51, the sacrificial material region 43 is not removed. It ensures increased structural stability of the FBAR device compared to a case of previously forming an air gap, even when the dry film is formed throughout the upper surface of the FBAR device for the formation of the side wall structure 51. Meanwhile, when the dry film is selectively removed to complete the side wall structure 51, the passivation layer 49 serves to protect the resonance unit including the upper electrode 46.

After forming the side wall structure 51, as shown in FIG. 4C, the sacrificial material layer 43 is removed, resulting in an air gap (A). During this etching process, although the photoresist film 40 (referring to FIG. 3g) must be previously removed for the formation of the side wall structure 51, the upper electrode 46 can be appropriately protected by the passivation layer 49.

In succession, as shown in FIG. 4d, another dry film is applied onto the side wall structure 51, so as to form a roof structure 52. In this way, an FBAR device package 60 using dry films can be completed. The FBAR device package 60 is connectable to an exterior circuit in a wire bonding manner by making use of the connection pads 47 and 48, which are exposed out of a resulting cap structure 50, as shown in FIG. 4e. Although the present embodiment illustrates a wire bonding structure, the present invention is not limited thereto, and the wire bonding structure may be substituted with a flip chip bonding structure.

In the present embodiment, although an example of the formation of the cap structure using dry films is explained, the FBAR device package of the present invention may be embodied to a wafer level package using a cap wafer, which is made of a material similar to that of a device wafer.

As apparent from the above description, the present invention provides an FBAR device which is configured so that a passivation layer is formed to completely cover a resonance unit including upper and lower electrode and a piezoelectric layer, thereby enabling appropriate easy adjustment of a resonant frequency of the resonance unit and protecting the resonance unit from unintentional influences of subsequent processes.

Further, according to the present invention, through the formation of the passivation layer, during an air gap formation process and a cap structure formation process included in a chip scale packaging or wafer level packaging, the resonance unit of the FBAR device can be safely protected, resulting in stable maintenance of the appropriately adjusted resonant frequency thereof, and considerable enhancement in reliability of the FBAR device.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A film bulk acoustic wave resonator (FBAR) device comprising:
a substrate;
a resonance unit including a lower electrode, a piezoelectric film, and an upper electrode, which are successively stacked on the substrate; and
a passivation layer formed substantially throughout an upper surface and a peripheral surface of the resonance unit in order to protect the resonance unit,
wherein a partial region of the passivation layer located on at least the upper electrode has a thickness required to compensate for a difference between a resonant frequency of the resonance unit and a desired target resonant frequency.

2. The device as set forth in claim 1, wherein the passivation layer is made of an oxide or nitride composed of elements selected from among the group consisting of Si, Zr, Ta, Ti, Hf, and Al.

3. The device as set forth in claim 2, wherein the passivation layer is made of a material selected from among the group consisting of SiO₂, Si₃N₄, HfO, Al₂O₃, AlN and AlNOₓ.

4. The device as set forth in claim 1, wherein the passivation layer is formed by sputtering, evaporation, or chemical vapor deposition (CVD).

5. The device as set forth in claim 1, further comprising:
connection pads formed on the substrate so that they are connected to the upper and lower electrodes, respectively.

6. The device as set forth in claim 5, wherein the connection pads are made of Au or Al.

7. The device as set forth in claim 1, wherein the substrate has an air gap formed at a region where the resonance unit is formed thereabove.

8. The device as set forth in claim 1, wherein the substrate has a reflective film structure obtained through bragg reflection.

9. A method of manufacturing an FBAR device comprising the steps of:
a) preparing a substrate;
b) forming a resonance unit by successively stacking a lower electrode, a piezoelectric film, and an upper electrode on the substrate;
c) calculating a thickness of the resonance unit required to compensate for a difference between a resonant frequency of the resonance unit and a desired target resonant frequency; and
d) forming a passivation layer substantially throughout an upper surface and a peripheral surface of the resonance unit for protecting the resonance unit so that a partial region of the passivation layer located on at least the upper electrode has the calculated thickness.

10. The method as set forth in claim 9, wherein the passivation layer is made of an oxide or nitride composed of elements selected from among the group consisting of Si, Zr, Ta, Ti, Hf, and Al.

11. The method as set forth in claim 10, wherein the passivation layer is made of a material selected from among the group consisting of SiO₂, Si₃N₄, HfO, Al₂O₃, AlN and AlNOₓ.

12. The method as set forth in claim 9, wherein the step d) is performed by sputtering, evaporation, or chemical vapor deposition.

13. The method as set forth in claim 9, before the step d), further comprising the step of:
e) forming connection pads on the substrate so that they are connected to the upper and lower electrodes, respectively.

14. The method as set forth in claim 13, wherein the connection pads are made of Au and/or Al.

15. The method as set forth in claim 13, wherein the step d) includes the steps of:
d-1) forming the passivation layer on the substrate above the resonance unit so that the partial region of the passivation layer located on at least the upper electrode has the calculated thickness; and
d-2) selectively removing the passivation layer so that partial regions of the connection pads to be bonded to an exterior circuit are exposed to the outside.

16. The method as set forth in claim 9, wherein the step a) includes the steps of:
a-1) forming a sacrificial material region at the substrate, the sacrificial material region being for use in the formation of an air gap; and
a-2) forming an insulation layer on the sacrificial material region, further comprising the steps of:
f) selectively removing the insulation layer, so as to form a via hole communicating with the sacrificial material region; and
g) removing the sacrificial material region through the via hole, so as to form the air gap.

17. The method as set forth in claim 16, wherein the step d-2) and the step f) are simultaneously performed through a single process using a photoresist film.

18. The method as set forth in claim 16, wherein: the sacrificial material region is made of a polysilicon material;
the step g) is an etching step of the sacrificial material region using XeF₂; and
in the step g), the passivation layer protects the upper electrode.

19. The method as set forth in claim 9, wherein the step a) provides the substrate having a reflective film structure obtained through bragg reflection.

20. A method of manufacturing an FBAR device package comprising the steps of:
a) preparing a substrate;
b) forming a resonance unit by successively stacking a lower electrode, a piezoelectric film, and an upper electrode on the substrate;
c) calculating a thickness of the resonance unit required to compensate for a difference between a resonant frequency of the resonance unit and a desired target resonant frequency;
d) forming a passivation layer substantially throughout an upper surface and peripheral surface of the resonance unit for protecting the resonance unit so that a partial region of the passivation layer located on at least the upper electrode has the calculated thickness; and
e) forming a cap structure so as to seal the resonance unit formed with the passivation layer.

21. The method as set forth in claim 20, wherein the step e) includes the steps of:
e-1) forming a side wall structure surrounding the resonance unit by applying a first dry film; and
e-2) forming a roof structure on the side wall structure by applying a second dry film thereon.

22. The method as set forth in claim 21, wherein the step a) includes the step of a-1) forming a sacrificial material region at the substrate for the formation of an air gap,
further comprising the step of:
f) removing the sacrificial material region for the formation of the air gap, after the step e-1) and before the step e-2).

23. The method as set forth in claim 20, further comprising the step of:
g) forming connection pads on the substrate so that they are connected to the upper and lower electrodes, respectively, before the step d).

24. The method as set forth in claim 23, wherein the connection pads are made of Au.

25. The method as set forth in claim 23, wherein the step d) includes the steps of:
d-1) forming the passivation layer on the substrate above the resonance unit so that the partial region formed on at least the upper electrode has the calculated thickness; and
d-2) selectively removing the passivation layer so that partial regions of the connection pads to be bonded to an exterior circuit are exposed to the outside.

26. The method as set forth in claim 25, wherein the step a) includes the steps of:
a-1) forming a sacrificial material region at the substrate for the formation of an air gap, and
a-2) forming an insulation layer on the sacrificial material region,
further comprising:
h) selectively removing the insulation layer, so as to form a via hole communicating with the sacrificial material region; and
i) removing the sacrificial material region through the via hole, so as to form the air gap.

27. The method as set forth in claim 26, wherein the step d-2) and the step h) are simultaneously performed through a single process using a photoresist film.

28. The method as set forth in claim 26, wherein: the sacrificial material region is made of a polysilicon material;
the step i) is an etching step of the sacrificial layer using XeF₂; and
in the step i), the passivation layer protects the upper electrode.

29. The method as set forth in claim 20, wherein the step a) provides the substrate having a reflective film structure obtained through bragg reflection.
